(19) United States
(12) Patent Application Publication
(10) Pub. No.: US 2007/0120076 A1
(43) Pub. Date: May 31, 2007

(54) Integrated ionizers for process metrology equipment

(75) Inventors: Scott Gehlke, Berkeley, CA (US); John E. Menear, Santa Cruz, CA (US); Cheryl Sue Avery, Dublin, CA (US)

Correspondence Address: MKS Instruments Inc., 1750 North Loop Road, Alameda, CA, 94502, US

(73) Assignee: MKS Instruments Inc.

(21) Appl. No.: 11/542,401

(22) Filed: Oct. 3, 2006

Related U.S. Application Data
(60) Provisional application No. 60/726,004, filed on Oct. 11, 2005.
(60) Provisional application No. 60/788,814, filed on Apr. 3, 2006.

(51) Int. Cl. H01J 37/08

(52) U.S. Cl. 250/492.21

(57) ABSTRACT

Ionizers are integrated with the computer and software that is used to operate process equipment. Communication is bidirectional. Operating information from the ionizer is displayed on the equipment computer terminal. Commands from the equipment computer control the ionizer. This enables the ionizer to react to ionizing requirements that change with time.

### CROSS-REFERENCE TO RELATED APPLICATIONS

This application claims priority to provisional application No. 60/726,004 filed Oct. 11, 2005 entitled “Integrated Ionizers For Process and Metrology Equipment”.

This application also claims priority to provisional application No. 60/788,814 filed Apr. 3, 2006 entitled “Integrated Ionizers for Process and Metrology Equipment #2”.

### STATEMENT REGARDING FEDERALLY SPONSORED RESEARCH

Not Applicable

### REFERENCE TO A MICROFICHE APPENDIX

Not Applicable

### BACKGROUND OF THE INVENTION

1. Field of the Invention

This invention relates to ionizers, which are designed to remove or minimize static charge accumulation. Ionizers remove static charge by generating air ions and delivering those ions to a charged target.

Some ionizers are used inside process equipment or metrology equipment. Examples of application fields include semiconductor, disk drive, and flat panel display.

The ionizer(s) is frequently placed inside the loading mini-environment. It may also be placed inside the actual process or measurement chamber. Ions protect the product from static buildup during movement through the equipment.

In recent history, ionizer control has operated separate from the computer and software that controls plus monitors the equipment itself. The equipment computer controls such functions as robot movement, stage movement, wafer pre-aligning, wafer positioning, time periods at various stations, and coordination among movements.

The ionizer is controlled by its own controller or computer, and the variables controlled include power, voltage at the emitters, on times, off times, and pulse frequency. These variables are set to achieve the desired discharge time, balance, offset, and swing. Normally, these parameters are set at installation, and remain constant until the next scheduled maintenance date.

2. Description Of Related Art

Signals from the ionizer controller are separate from the signals that control the equipment. Signals originating from the equipment's computer (hardware and software) do not make adjustments to the ionizer.

Signals originating from the ionizer's controller (hardware and software) do not send status information to the equipment's computer.

Advantages are available from integrating the ionizer control into the equipment control, and allowing information to flow in both directions between the ionizer system and the equipment computer. That integration and control are the subject of this disclosure.

### BRIEF SUMMARY OF THE INVENTION

The present invention integrates ionizer control into the equipment computer (hardware and software).

Communication between the ionizer and the equipment is bidirectional. The ionizer can be controlled via commands generated by the equipment, and equipment can be controlled via commands generated by the ionizer.

This creates control and feedback that is not possible with separate control.

An example is ionizer adjustment to decrease discharge time. Consider a charged wafer that has just been taken out of the equipment's process chamber and positioned below the ionizer. At this time, the most important function of the ionizer is to quickly neutralize the charge. With integrated control, the power to the ionizer can be increased (relative to baseline settings) or the frequency can be decreased or both. In response, the discharge time will decrease. Swing or offset voltage will increase, and balance may be affected. However, the tradeoff is appropriate at this specific time.

The steps involved may include any or all of the following:

(1) wafer charge is sensed by a sensor as the wafer is removed from the process chamber,

(2) the wafer path and projected travel path is retrieved from the robot movement program,

(3) the time at which the wafer is positioned directly under the ionizer is determined,

(4) power to the ionizer is changed when the wafer is directly below (the power applied could also adjust for the air velocity within the environment),

(5) the frequency (timing) of the ionizer is decreased when the wafer is directly below (the frequency applied could also adjust for the air velocity within the environment),

(6) based on a very high measured level of wafer charge, the robot might hesitate for an additional 2 seconds beneath the ionizer,

(7) the wafers moves onward,

(8) the ionizer restores its baseline settings, initiates new settings for another priority function, or goes into “sleep mode”.

Another example application is adjusting the ionizer for distance. When wafers are in a FOUP, the wafer in slot 25 is closer to a ceiling-mounted ionizer than the wafer in slot 1. At constant ionizer settings, the wafer in slot 25 experiences a shorter discharge time and a larger swing. The wafer in slot 1 experiences a longer discharge time and a smaller swing. And the balance near slot 25 may be different from the balance near slot 1. An integrated ionizer can adjust for the height difference because the robot's end effector height is known. The steps involved may include any or all of the following:

(1) as the robot prepares to pick up a wafer, the equipment controller sends the slot number to the ionizer control circuit,

(2) the ionizer adjusts power, on-time, off-time, and frequency based on previously determined performance maps. Balance, discharge time, and swing are held in a tight range regardless of which wafer slot is addressed.

(3) after all wafers have been processed, the ionizer returns to a preset value or goes into “sleep mode”.

Another example application is using a “sleep mode” or “idle mode” to achieve increased emitter life and reduced maintenance. Between active processing periods (where wafers are not being moved or no FOUP is present), the ionizer can be programmed to enter a reduced power condition. Under some circumstances, power may be turned off. The low power mode has the potential to reduce contamination buildup on the emitters, and increase the time between scheduled maintenance. At lower voltage, less contamination builds up on the emitters.

Another example application is reacting to a door opening or other perturbation of the work environment. Most mini-environments have door interlocks. If a door is opened, an alarm sounds and robot functions cease. The interlock state can be shared with the ionizer. Ionizer settings may be adjusted to reflect the door opening, or power can be turned off.

Another example application is backside ionizer activation. An ionizer under the wafer may be periodically activated, whereas normally it is not active. This would be useful for the case where air from a backside ionizer is blown upward toward the back of the wafer. Without a wafer over the ionizer, air flow within the mini- environment would be disrupted. So, it is appropriate to use the backside ionizer only when a wafer is above it. Since the robot coordinates are known, the ionizer can be activated only when a wafer is above.

Another example application is balance adjustment at the FOUP. A static charge goal for equipment is to eliminate wafer charges before sending wafers to another processing tool. When the last wafer has been processed, the integrated system can send a signal to the ionizer. In response, the ionizer adjusts itself for optimum balance at the FOUP. Other locations within the mini-environment can be temporarily ignored because no wafers are present at these other locations. As a side note, balance at the FOUP is always important. Each wafer in a 25 wafer FOUP spends roughly 96% of its time in the FOUP.

Another example application is ionizer adjustment to protect a critical metrology zone. Some metrology tools are extremely sensitive to vibration (notably, thin film measurement tools). Since fan speed is related to vibration, air velocity is often reduced to the bare minimum—often at the expense of contamination control. A more desirable approach would be to lower the air flow only during the actual measurement because stage movements are minimal at this time. (Fast, high amplitude moves occur during loading and unloading.) It is reasonable to expect equipment vendors to adopt this approach in the near future. And as a consequence of changed air flow, altered ionizer setting will be required. When the stage indicates that a wafer has been positioned for measurement, air flow can be reduced. And simultaneously, ionizer settings are changed according to pre-established maps. After the measurement, air flow is increased to provide better contamination protection, and ionizer settings are restored to baseline.

Another example application is active monitoring of ionizer performance through the equipment computer. Equipment users would like to actively monitor ionizer performance. A commonly expressed need is the ability to know whether the ionizer is performing within specification. The information is not readily available. Yet the ionizer controller has the information. This can be remedied by sending the existing ionizer data to the equipment monitor. In the preferred mode, the data is sent in digital form.

Some or all of the following items may be required to accomplish the stated goals. They are:
an ionizer whose settings are stored in digital form,
an ionizer whose self-diagnostic data and current status data are stored in digital form,
an ionizer whose settings may be changed via a digital command,
compatibility between the ionizer and equipment software,
hardware to effect compatibility between the ionizer and equipment software,
translation between equipment and ionizer software,
hardware to effect tranlation between the ionizer and equipment software,
the capability to send ionizer information to the equipment,
the capability to send equipment information to the ionizer,
the ability to transmit both equipment and ionizer information on the equipment buss.

### BRIEF DESCRIPTION OF THE SEVERAL VIEWS OF THE DRAWINGS

FIG. 1 is a schematic that shows the system hardware. The existing customer equipment consists of the Equipment and the Equipment controller, linked by the SECS2 protocol over TCP/IP.

FIG. 2 is a schematic that shows the software connection between the components in the enabler chain. (Both physical connections are the same: TCP/IP.)

FIG. 3 shows the interconnection with a communication port for remote or intermittent communication between the ionizer and the remote computer.

### DETAILED DESCRIPTION OF THE INVENTION

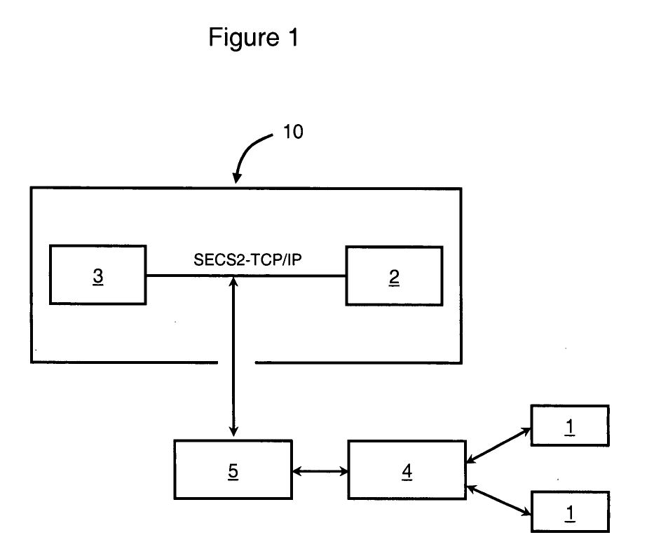

Refer to FIG. 1. The tool-bus connection between the ionizers 1 and the process or metrology tool 10 requires an intermediate module 4 to provide hardware and software compatibility.

For the majority of process or metrology tool 10, the interface is SECS2 over TCP/IP. The SECS2 protocol is a point-to-point protocol, and is not designed for multiple talkers or listeners. There are several industry solutions that overcome this limitation. Each provides an interface to the SECS2-TCP/IP interface that allows multiple talkers and listeners, as well as a general interface to the ionizer 1.

The hardware for this system is shown in FIG. 1. The existing process or metrology tools 10 consist of the equipment 2 and the equipment controller 3, linked by the SECS2 protocol over TCP/IP.

A SECS2 translator 5 allows additional components on the SECS2 connection. The SECS2 translator 5 provides a general multi-point protocol, and provides a hardware connection, usually TCP/IP.

An intermediate module 4 interfaces to the SECS2 translator 5 and provides the final translation to the ionizer 1 protocol over RS-485 (but not limited to RS-485). In an alternate configuration, the ionizer 1 could be designed to connect directly to the SECS2 translator 5. But since an intermediate module 4 already exists, it is a logical choice to provide the final translation.

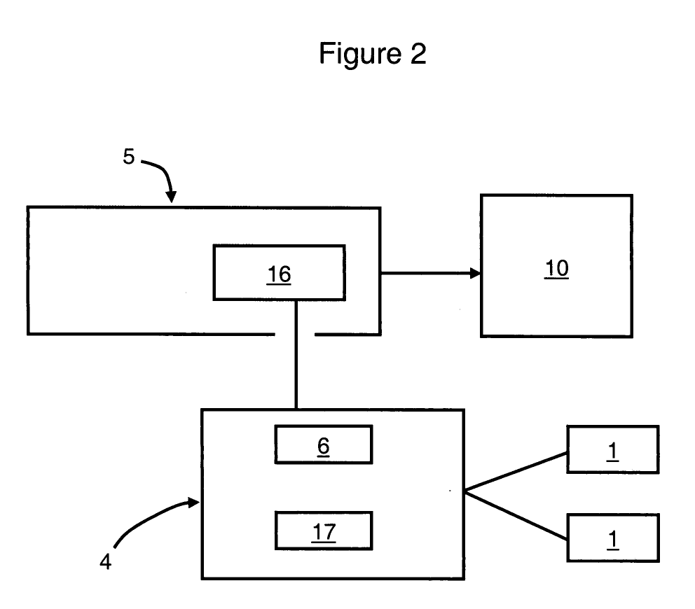

FIG. 2 shows the software connection between the components in the enabler chain. In this diagram, both physical connections are the same: TCP/IP.

The SECS2 translator 5 provides some multi-connection protocol suitable for TCP/IP, such as XML. When the intermediate module 4 connects to the SECS2 translator 5, it uses a driver code module 6 to coordinate the information from the SECS2 translator 5 for use by the ionizer 1. A response algorithm 17 provides adjustment input to the ionizer 1.

Once the hardware has been connected as shown, the step-by-step process for Toolbus control is as follows:

1) Using a previously stated example, a charged wafer has just been taken out of the equipment's 2 process chamber and positioned below the ionizer 1. The notification of this event travels over the SECS2 connection.

2) The SECS2 translator 5 intercepts the notification from the SECS2 bus and translates the SECS2 protocol into a general-purpose protocol like XML. This is sent to the intermediate module 4.

3) The intermediate module 4 receives the message from the SECS2 translator 5 and decodes the protocol to determine that the wafer transfer has occurred.

4) Another section of code in the intermediate module 4 determines from the message that the ionizer 1 level needs to be increased or the emitter frequency decreased.

5) As a final step, the intermediate module 4 encodes a command to the ionizer 1 to increase the level, and sends it over the RS-485 (or similar) bus.

Sensors are combined into the overall equipment/ionizer integration. All sensor information is available at the ionizer 1 level or at the process or metrology tool 10 computer level. For example, EMI (electromagnetic interference) sensors provide feedback concerning the number of electrostatic discharge events in the working environment.

Surface charge sensors are also integrated. These sensors indicate the level of charge on a product, or on objects close to the product.

Other integrated sensors are charge plate monitors for balance and discharge time, and remote ion current sensors.

Any sensor normally used for assessing the quality of ionization may be used.

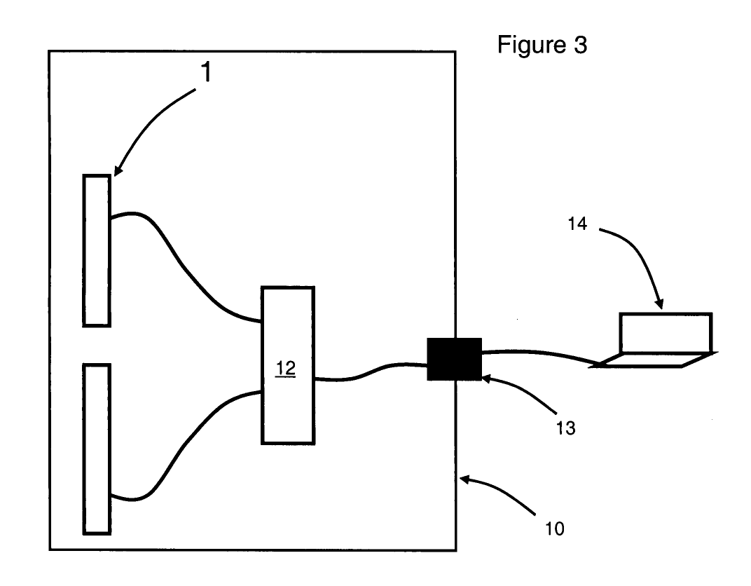

In some instances, process and metrology tool 10 owners do not want full time communication between the process and metrology tool 10 and the ionizers 1. FIG. 3 describes the solution.

One or more ionizers 1 are controlled by a stand-alone controller 12. The stand-alone controller 12 has a communication port 13 which can talk to a remote computer 14. As shown, the computer 14 is a laptop.

When the process and metrology tool 10 owner wants communication, he plugs his computer into the communication port 13. In a preferred installation, the communication port 3 is located on the outside surface of the process and metrology tool 10 where access is easy.

The invention claimed is:

1. An ionizer for removing static charge that is integrated into process or metrology equipment comprising:
one or more ionizers;
hardware that allows bidirectional communication between the ionizer controller and the process or metrology tool computer; and
software that allows said bidirectional communication between said ionizer controller and said process or metrology tool computer.

2. Claim 1 where said hardware includes a SECSII translator.

3. Claim 1 where said hardware includes an intermediate module.

4. Claim 1 where said bidirectional communication utilizes TCP/IP.

5. Claim 1 where said hardware includes a SECS2 translator plus an intermediate module.

6. Claim 1 where said hardware interface is SECS2 over TCP/IP.

7. Claim 1 where said software contains a driver for a SECS2 translator.

8. Claim 1 where said software contains a driver for an intermediate module.

9. Claim 1 where said ionizer is connected directly to a SECS2 translator.

10. Claim 1 further comprising measurement sensors.

11. Claim 1 where an intermediate module receives a data stream from a SECS2 translator, and decodes said data stream.

12. Claim 1 where an intermediate module encodes a command, and forwards said command to said ionizer.

13. Claim 2 where said SECS2 translator intercepts the notification from a SECS2 bus and translates a SECS2 protocol into a general-purpose protocol.

14. Claim 13 where said general-purpose protocol is XML.

15. Claim 3 where said intermediate module includes a response algorithm.

16. Claim 3 where said intermediate module includes a response algorithm and a SECS2 translator.

17. Claim 3 where said intermediate module interfaces to a SECS2 translator and provides the final translation to the ionizer protocol over RS-485 .

18. Claim 10 where said measurement sensor comprises a surface charge sensor.

19. Claim 10 where said measurement sensor comprises a charge plate monitor.

20. Claim 10 where said measurement sensor comprises a EMI sensor.

21. Claim 10 where said measurement sensor comprises a remote current sensor.

22. A method of utilizing an ionizer that is integrated with the equipment computer to control the ionizer settings, comprising:
sending the control command from said equipment computer;
translating said control command into a format readable by the ionizer; and
forwarding an adjustment to the ionizer module.

23. Claim 22 where said ionizer settings include ionizer power.

24. Claim 22 where said ionizer settings include ionizer voltage to the emitters.

25. Claim 22 where said ionizer settings include ionizer frequency.

26. Claim 22 where said ionizer settings include ionizer on times.

27. Claim 22 where said ionizer settings include ionizer off times.

28. Claim 22 where the command to control or change ionizer settings is originated by the equipment computer.

29. A method of utilizing an ionizer that is integrated with the equipment computer to display ionizer conditions at the equipment computer monitor, comprising:
sending said ionizer conditions in digital form from the ionizer controller;
translating said ionizer conditions into a format readable by the equipment computer; and
forwarding said ionizer conditions to the equipment monitor for display.

30. Claim 29 where said ionizer conditions include balance.

31. Claim 29 where said ionizer conditions include discharge time.

32. Claim 29 where said ionizer conditions include ion current.

33. Claim 29 where said ionizer conditions include surface charge.

34. Claim 29 where said ionizer conditions include power level.

35. Claim 29 where said ionizer conditions include on time.

36. Claim 29 where said ionizer conditions include off time.

37. Claim 29 where said ionizer conditions include frequency.

38. Claim 29 where said ionizer conditions include alarm status.

39. An apparatus for controlling or monitoring ionizers with a remote computer comprising:
one or more ionizers;
a communication port;
a remote computer;
software which allows said remote computer and said ionizer to communicate.

40. Claim 39 which further comprises a stand-alone controller which is disposed between said ionizer and said connector.

41. Claim 39 where said communication port is located on a wall of the equipment.

42. Claim 41 where said communication port is accessible without opening any equipment doors.

43. Claim 39 where said remote computer and said ionizer communicate bi-directionally.

44. A method of controlling or monitoring ionizers with a remote computer comprising:
providing a communication port on a surface of the equipment to be monitored or controlled;
connecting said communication port to one or more ionizers;
plugging a remote computer into said communication port;
sending data between said ionizer and said remote computer.

45. Claim 44 where said communication port is a commercially available connector.

46. Claim 44 where said surface of the equipment is an external surface.

47. Claim 44 where said sending is bi-directional.

48. Claim 44 where a control module is disposed between said one or more ionizers and said communication port.

49. Claim 44 further comprising a step of unplugging said remote computer from said communication port.
